(19) United States
(12) Patent Application Publication
(10) Pub. No.: US 2020/0028014 A1
(43) Pub. Date: Jan. 23, 2020

(54) PHOTOVOLTAIC DEVICE INTERCONNECT, PHOTOVOLTAIC DEVICE INCLUDING SAME, AND METHOD OF FORMING INTERCONNECT

(71) Applicant: BEIJING APOLLO DING RONG SOLAR TECHNOLOGY CO., LTD., Beijing (CN)

(72) Inventors: Robel FESSEHATZION, Campbell, CA (US); Jochen TITUS, San Jose, CA (US)

(21) Appl. No.: 16/041,137

(22) Filed: Jul. 20, 2018

(51) Int. Cl. H01L 31/05; H01L 31/032; H01L 31/0224; H01L 31/18

(52) U.S. Cl. CPC H01L 31/0508; H01L 31/0512; H01L 31/18; H01L 31/022466; H01L 31/0322

(57) ABSTRACT

A photovoltaic device interconnect contains a first connection region, a second connection region, and an overlap region disposed between the first and second connection regions. The interconnect includes a first dielectric layer disposed in the first connection region and the overlap region, a second dielectric layer disposed in the second connection region and overlapped with the first dielectric layer in the overlap region, an electrically conductive element including a wire or a metal foil, disposed on an upper surface of the first dielectric layer, and an electrically conductive network of nanowires disposed on a lower surface of the second dielectric layer and electrically connected to the conductive element in the overlap region.

### FIELD

The present disclosure is directed generally to photovoltaic device interconnects, photovoltaic devices include the same, and methods of forming the same.

### BACKGROUND

Photovoltaic cells (e.g., solar cells) are currently being developed as a source of “green” energy. However, a fundamental shortcoming of solar cells is the difficulty and expense involved with installing and electrically connecting solar cells in an array.

### SUMMARY

According to various embodiments of the present disclosure, provided is a photovoltaic device interconnect having a first connection region, a second connection region, and an overlap region disposed between the first and second connection regions, the interconnect comprising: a first dielectric layer disposed in the first connection region and the overlap region; a second dielectric layer disposed in the second connection region and overlapped with the first dielectric layer in the overlap region; an electrically conductive element comprising a wire or metal foil disposed on an upper surface of the first dielectric layer; and an electrically conductive network of nanowires disposed on a lower surface of the second dielectric layer and electrically connected to the conductive element in the overlap region.

According to various embodiments of the present disclosure, provided is a method of making a photovoltaic device interconnect, comprising: disposing an electrically conductive element comprising a conductive wire or metal foil on a transparent first dielectric layer; applying the nanowire solution to a transparent second dielectric layer to form an electrically conductive network of nanowires on the second dielectric layer; partially overlapping the first and second dielectric layers; and adhering overlapped portions of the first and second dielectric layers to one another, such that a portion of the conductive element electrically contacts a portion of the network.

### BRIEF DESCRIPTION OF THE DRAWINGS

FIG. 1A is a vertical cross-sectional view of a photovoltaic device, according to various embodiments of the present disclosure, FIG. 1B is a top plan view of one embodiment of the device of FIG. 1A, and FIG. 1C is a top plan view of another embodiment the device of FIG. 1A.

FIGS. 2A-2C are vertical cross-sectional views showing a method of manufacturing an interconnect, according to various embodiments of the present disclosure.

FIG. 3 is a vertical cross-sectional view of two connected photovoltaic devices 100A, 100B, according to various embodiments of the present disclosure.

FIG. 4 shows an exemplary apparatus for forming the solar cells as illustrated in FIG. 1A.

### DETAILED DESCRIPTION

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element. As used herein, an element is “configured” to perform a function if the structural components of the element are inherently capable of performing the function due to the physical and/or electrical characteristics thereof.

It will also be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Ranges may be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. In some embodiments, a value of “about X” may include values of +/−1% X. It will be further understood that the endpoints of each of the ranges are significant both in relation to the other endpoint, and independently of the other endpoint. Herein, “substantially all” of an element may refer to an amount of the element ranging from 98-100% of the total amount of the element. In addition, when a component is referred to as being “substantially free” of an element, the component may be completely free of the element or may include a trace amount (e.g., 1% or less) of the element.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (CIGS).

Thin-film photovoltaic cells (also known as solar cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

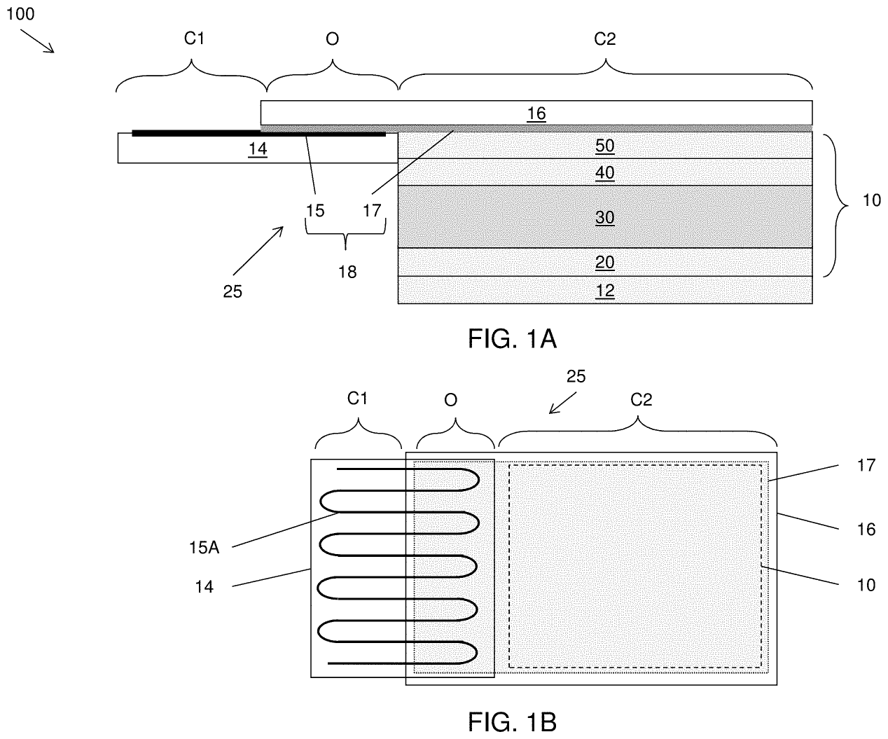

FIG. 1A is a vertical cross-sectional view of a photovoltaic device 100, according to various embodiments of the present disclosure, FIG. 1B is a top plan view of one embodiment of the device 100 of FIG. 1A, and FIG. 1C is a top plan view of another embodiment of device of FIG. 1A.

Referring to FIGS. 1A-1C, the device 100 may include a solar cell 10, a substrate 12, and an interconnect 25. The solar cell 10 may completely cover the substrate 12. The substrate 12 may be formed of a conductive material, such as a metal or metal alloy foil. For example, the substrate 12 may be formed of aluminum, titanium, or a metal alloy such as stainless steel. The substrate 12 may be formed by cutting a metallic web substrate that is fed through a system including one or more process modules, as discussed below in detail. The substrate 12 may comprise a part of the anode electrode of the cell 10. Thus, the anode of the cell 10 may be referred to as a back electrode. Alternatively, the conductive substrate 12 may be an electrically conductive or insulating polymer foil. Still alternatively, the substrate 12 may be a stack of a polymer foil and a metallic foil. The thickness of the substrate 12 can be in a range from 100 microns to 2 mm, although lesser and greater thicknesses can also be employed.

### Solar Cells

The solar cell 10 may include a first electrode 20 (e.g., anode), a p-doped semiconductor layer 30, an n-doped semiconductor layer 40, a second electrode 50 (e.g., cathode), and an optional antireflective (AR) layer. The anode 20, the cathode 50, the p-doped semiconductor layer 30, the n-doped semiconductor layer 40, and the optional AR layer may be in the form of a stack of various films that form a photovoltaic structure.

The anode 20 may comprise any suitable electrically conductive layer or stack of layers. For example, the anode 20 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. The anode 20 can have a thickness in a range from 500 nm to 1 micron, although lesser and greater thicknesses can also be employed.

The p-doped semiconductor layer 30 can include a p-type, sodium doped copper indium gallium selenide (CIGS), which functions as a semiconductor absorber layer. The thickness of the p-doped semiconductor layer 30 can be in a range from 1 microns to 5 microns, although lesser and greater thicknesses can also be employed.

The n-doped semiconductor layer 40 includes an n-doped semiconductor material such as CdS, ZnS, ZnSe, or an alternative metal sulfide or a metal selenide. The thickness of the n-doped semiconductor layer 40 is typically less than the thickness of the p-doped semiconductor layer 30, and can be in a range from 50 nm to 100 nm, although lesser and greater thicknesses can also be employed. The junction between the p-doped semiconductor layer 30 and the n-doped semiconductor layer 40 is a p-n junction. The n-doped semiconductor layer 40 can be a material which is substantially transparent to at least part of the solar radiation. The n-doped semiconductor layer 40 is also referred to as a buffer layer. Other semiconductor materials, such as GaAs, silicon, CdTe, etc., may be used for the p-doped and/or n-doped semiconductor layers 30, 40.

The cathode 50 may be formed of one or more layers of a transparent conductive material. Exemplary transparent conductive materials include ZnO, indium tin oxide (ITO), Al doped ZnO (“AZO”), or a combination or stack of higher resistivity AZO and lower resistivity ZnO, ITO and/or AZO layers.

The optional AR layer can decrease the amount of light that is reflected off the top surface of the photovoltaic cell 10, which is the surface that is located on the opposite side of the substrate 12. In one embodiment, the AR layer can be a coating deposited directly on the top surface of the second electrode 50. Alternatively or additionally, a transparent cover glass or polymer layer can be disposed over the photovoltaic cell in a final product, and an antireflective coating can be formed on either side, or on both sides, of the transparent cover glass.

### Solar Cell Interconnects

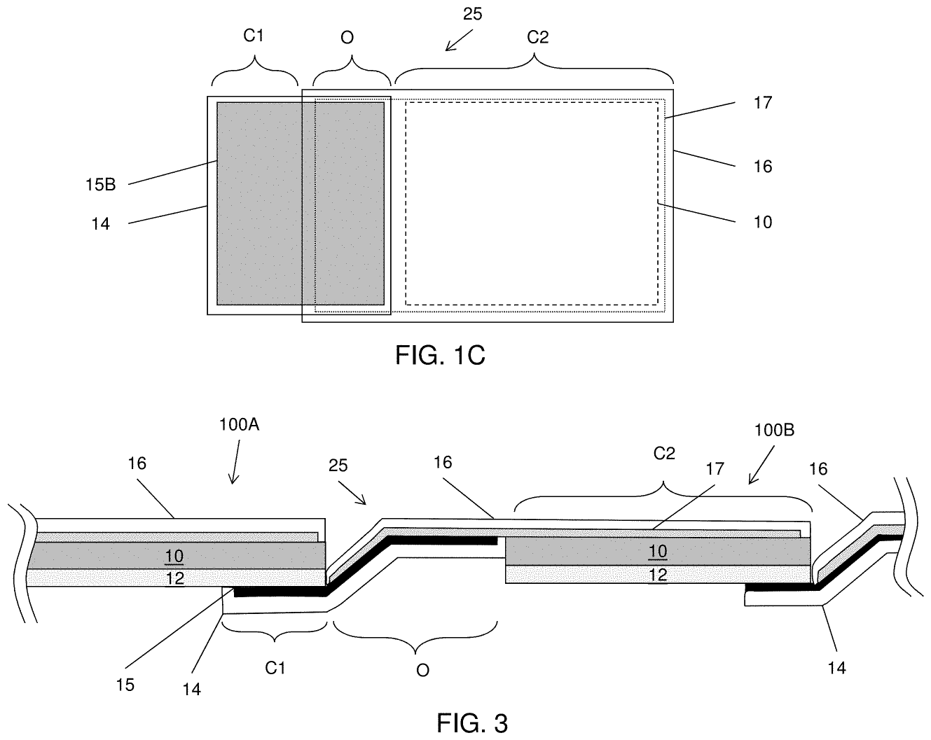

The interconnect 25 may be flexible and a least a portion of the interconnect 25 may be optically transparent. For example, a portion of the interconnect 25 may have an optical transparency of at least 75%, such as at least 80%, at least 85%, or at least 90%. The interconnect 25 may include a first dielectric layer 14, a second dielectric layer 16, and an electrically conductive hybrid layer 18, as shown in FIGS. 1A and 2C. The interconnect 25 may have a first contact region C1, a second contact region C2, and an overlap region O, as shown in FIGS. 1A and 2C. In the first contact region C1, the hybrid layer 18 may be exposed on an upper surface of the interconnect 25, such that the hybrid layer 18 may be electrically connected to a bottom first (e.g., anode) electrode of a second cell (not shown in FIG. 1A) and the cells may be electrically connected in series. In the second contact region C2, the hybrid layer 18 may be exposed on a lower surface of the interconnect 25 and the exposed surface may contact the cell 10, such that the hybrid layer 18 is electrically connected to the top second (e.g., cathode) electrode 50 of the cell 10. The dielectric layers 14, 16 may overlap one another in the overlap region O, so as to cover opposing sides of the hybrid layer 18.

The dielectric layers 14, 16 may be formed of a dielectric material, such as a polymer or the like. In some embodiments, one or more of the dielectric layers 14, 16 may be substantially optically transparent. In some embodiments, one or more of the dielectric layers 14, 16 may be formed of a flexible material, such as a transparent polymeric film, a transparent non-polymeric film, a transparent oligomer film, or a combination thereof. In various embodiments, the first dielectric layer 14 may have a smaller surface area than the second dielectric layer 16.

In some embodiments, the hybrid layer 18 may be a flexible layer formed of two or more electrical conductors. For example, the hybrid layer 18 may include an electrically conductive element 15 and an electrically conductive nanowire network 17. The conductive element 15 may be formed of a nontransparent material. For example, the conductive element 15 may include an electrically conductive wire 15A, as shown in FIG. 1B, or an electrically conductive metal foil 15B, as shown in FIG. 1C.

As shown in FIG. 1B, the wire 15A may be arranged in a serpentine pattern and may have a non-rectangular and substantially uniform cross-sectional shape in a plane perpendicular to the local lengthwise direction. For example, the wire 15A can have a substantially circular cross-sectional shape or an elliptical cross-sectional shape. The thickness of the wire 15A, which is defined as the maximum dimension of the non-rectangular and substantially uniform cross-sectional shape, can be in a range from 30 microns to 3 mm. In one embodiment, the thickness of the wire 15A can be in a range from about 60 microns to about 1.5 mm. In one embodiment, the thickness of the wire 15A can be in a range from about 120 microns to about 750 microns. In case the non-rectangular and substantially uniform cross-sectional shape is a circle, the maximum lateral dimension can be the diameter of the zig-zag conductive wire 15A. Alternatively, the wire 15A may have a rectangular cross sectional shape. In other embodiments, conductors other than the wire 15A, such as conductive traces or strips, may be used in place of the conductive wire 15A.

Nanowires of the network 17 may be formed of an electrically conductive material, such as a metal including silver, nickel, copper, or combinations thereof. In some embodiments, the nanowires may be formed of carbon nanotubes or a conductive metal oxide, such as nickel oxide or silver oxide. The nanowires may have an average diameter ranging from about 10 to about 500 nm, such as from about 20 to 400 nm. The nanowires may have an average aspect ratio ranging from about 10 to 1000, such as from about 20 to 750. The concentration of the nanowires in the network 17 may be controlled such that the network 17 is optically transparent.

FIGS. 2A-2C are vertical cross-sectional views showing a method of manufacturing an interconnect 25, according to various embodiments of the present disclosure. Referring to FIG. 2A, the interconnect 25 may be formed by disposing the conductive element 15 on a surface of the first dielectric layer 14, and by forming the network 17 on a surface of the second dielectric layer 16. For example, the conductive element 15 may formed by attaching the conductive metal wire 15A to the first dielectric layer 14, as shown in FIG. 1B. The wire 15A may be applied in a serpentine pattern extending through the first contact region C1 and the overlap region O of the interconnect 25. An adhesive may be used to attach the conductive element 15 to the first dielectric layer 14. In other embodiments, the conductive element 15 may formed by attaching the metal foil 15B to the first dielectric layer 14, as shown in FIG. 1C.

In some embodiments, the network 17 may be formed by depositing nanowires to a surface of the second dielectric layer 16. For example, a nanowire solution may be applied to the second dielectric layer 16 using slot-die coating in a roll-to-roll process. In other embodiments, the nanowire solution may be applied by screen-printing, gravure printing, pad printing, inkjet printing, flexographic coating, spray coating, ultrasonic spray coating, or any other suitable coating process. In some embodiments, the nanowires may cover the entire surface of the second dielectric layer 16. In other embodiments, a peripheral region of the surface of the second dielectric layer 16 may remain uncoated with nanowires. In some embodiments, the nanowire solution may include an adhesive configured to attach the nanowires to the second dielectric layer 16. In other embodiments, an adhesive may be applied after depositing the nanowires.

As shown in FIGS. 2B and 2C, one of the dielectric layers 14, 16 may be inverted, and the dielectric layers 14, 16 may then be overlapped, such that the conductive element 15 and the network 17 electrically contact one another in the overlap region O to form the hybrid layer 18 and complete the interconnect 25. In some embodiments, an adhesive may be used to connect the dielectric layers 14, 16 at the overlap region O and/or connect the conductive element 15 and the network 17 to the dielectric layers 14, 16.

In various embodiments, the nanowires of the network 17 may be applied at a concentration that provides a substantially transparent, conductive network. For example, the network 17 may have an optical transparency of at least 80%, such as at least 85%, or at least 90%. The network 17 may have a sheet resistance of less than about 20 Ω/sq., such as less than about 10 Ω/sq. In some embodiments, the nanowires may cover at least about 12%, such as at least about 20%, or at least about 25%, such as from 12% to 40%, of the surface area of one surface of the second dielectric layer 16. In other embodiments, the concentration of the nanowires may be higher on a portion DI of the second dielectric layer 16 corresponding to the overlap region O as shown in FIG. 2A. In particular, the nanowire concentration may be higher in portion DI in order to provide a low resistance electrical connection between the conductive element 15 and the network 17. For example, the concentration of the nanowires in portion DI may be about 15% to about 100% higher, such as about 25% to about 75% higher, or about 50% higher, than a concentration of the nanowires on the remainder of the second dielectric layer 16, such as a portion corresponding to the second contact portion C2.

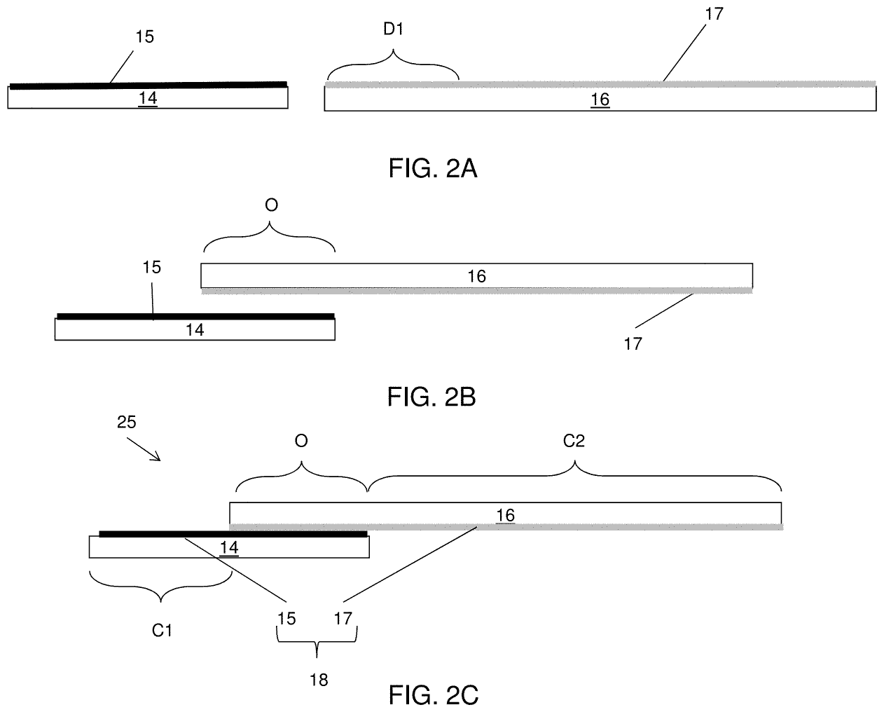

FIG. 3 is a vertical cross-sectional view of two connected photovoltaic devices 10A, 10B, according to various embodiments of the present disclosure. The devices 100A, 100B are similar to the device 100 of FIG. 1A, and like reference numbers refer to similar elements.

Referring to FIG. 3, the devices 100A, 100B are disposed in a “tiled” (e.g., “shingled”) configuration where a solar cell 10 of the device 100A is electrically connected to a solar cell 10 of the device 100B by an interconnect 25. In particular, the interconnect 25 of the device 100A electrically connects the anode the device 100A, via the substrate 12, to the cathode of the device 100B, such that the cells 10 are connected in series. The flexibility of the interconnect 25 allows the interconnect 25 to extend from the top of the cell 10 of the device 100B to below the cell 10 of the device 100A.

The interconnect 25 may be adhered to the cells 10 and/or substrate 12 using an adhesive that may be applied, for example, at the contact regions C1, C2. An adhesive may also be applied at the overlap region O to connect the dielectric layers 14, 16 of the interconnect 25. In some embodiments, at least the second contact region C2 of the interconnect 25 has an optical transmittance of at least 80%, such as at least 85%, or at least 90%. However, in other embodiments, the entire interconnect 25 may have an optical transmittance of at least 80%, such as at least 85%, or at least 90%.

As shown in FIG. 3, the first contact region C1 may contact at least part of the lower surface of the device 100A, so as to establish a suitable low resistance electrical connection with the substrate 12. However, in other embodiments, the first contact region C1 may completely cover the bottom of the device 100A. The overlap region O may be disposed between the devices 100A, 100B.

In some embodiments, the conductive element 15 may be recessed from edges of the first dielectric layer 14, and the network 17 may be recessed from edges of the second dielectric layer 16, so as to prevent the conductive element 15 and the network 17 from establishing electrical contacts with elements other than, for example, the substrate 12 of device 100A and the cathode of device 100B.

Although the cells 10 of are shown in FIG. 3 to be laterally spaced apart, in various embodiments, portions of the cells 10 may overlap vertically, such that the cells 10 are not laterally spaced apart. For example, in some embodiments, the overlap region O of the interconnect 25 may partially cover the cell 10 of the device 100B. In other words, a portion of the first dielectric layer 14 may be disposed on the upper surface of the cell 10 of the device 100B. Accordingly, the first dielectric layer 14 may prevent contact between the conductive element 15 and portions of the cell 10 of device 100B other than the cathode thereof.

The configuration of the interconnect 25 may be varied, and thus, is not limited to the configuration described above. Other interconnect configurations may be found in U.S. patent application Ser. No. 15/189,818, which is incorporated herein by reference, in its entirety. The devices 100A, 100B are shown as being laterally separated for clarity. However, the devices 100A, 100B may be laterally overlapped in the shingled configuration, such that an edge of the bottom surface of the substrate 12 of the device 100B overlaps with an edge of the top surface of the solar cell 10 of the device 100A.

According to various embodiments of the present disclosure, the use of nanowires in the interconnect 25 allows for the reduction of air gaps that may be formed, when an interconnect contains conductive materials other than nanowires disposed on the upper surface of a cell 10, such as an interconnect wire. Such air gaps may create optical losses due to additional interferences that reflect light and result in a reduction in cell efficiency. Such air gaps may also allow for moisture penetration. Accordingly, the use of nanowires provides unexpected benefits, as compared to conventional interconnects. Further, the use of a conductive element such as a conductive wire or metal foil provides a relatively inexpensive electrical connection in areas of the interconnect 25 contacting bottoms of the photovoltaic cells where reduced optical transmittance does not affect cell efficiency.

### Solar Cell Formation

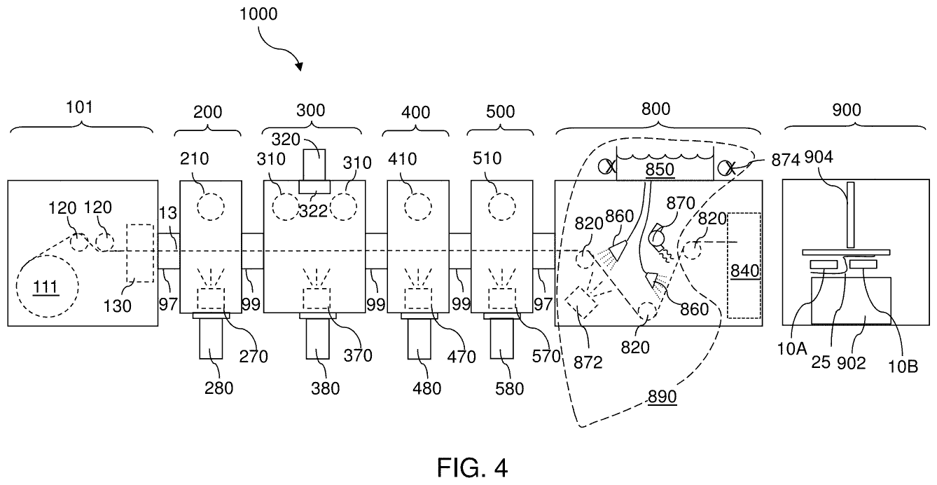

FIG. 4 shows an exemplary apparatus 1000 for forming the solar cell 10 on the substrate 12 illustrated in FIG. 1A. Referring to FIG. 4, the apparatus 1000 includes an input unit 101, a first process module 200, a second process module 300, a third process module 400, a fourth process module 500, and an output unit 800 that are sequentially connected to accommodate a continuous flow of a conductive web substrate 13 in the form of a web foil substrate layer through the apparatus. The apparatus 1000 may also include an interconnection module 900 located downstream of the output unit 800. The modules 101, 200, 300, 400, 500 may comprise the modules described in U.S. Pat. No. 9,303,316, issued on Apr. 5, 2016, incorporated herein by reference in its entirety, or any other suitable modules. The first, second, third, and fourth process modules 200, 300, 400, 500 can be under vacuum by first, second, third, and fourth vacuum pumps 280, 380, 480, 580, respectively. The first, second, third, and fourth vacuum pumps 280, 380, 480, 580 can provide a suitable level of respective base pressure for each of the first, second, third, and fourth process modules 200, 300, 400, 500, which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules 200, 300, 400, 500 is interconnected employing a vacuum connection unit 99, which can include a vacuum tube and an optional slit valve that enables isolation while the web substrate 13 is not present. The input unit 101 can be connected to the first process module 200 employing a sealing connection unit 97. The last process module, such as the fourth process module 500, can be connected to the output unit 800 employing another sealing connection unit 97.

The web substrate 13 can be a metallic or polymer web foil that is fed into a system of process modules 200, 300, 400, 500 as a web for deposition of material layers thereupon to form the photovoltaic cell 10. The web substrate 13 can be fed from an entry side (i.e., at the input module 101), continuously move through the apparatus 1000 without stopping, and exit the apparatus 1000 at an exit side (i.e., at the output module 800). The web substrate 13, in the form of a web, can be provided on an input spool 111 provided in the input module 101.

The web substrate 13, as embodied as a metal or polymer web foil, is moved throughout the apparatus 1000 by input-side rollers 120, output-side rollers 820, and additional rollers (not shown) in the process modules 200, 300, 400, 500, vacuum connection units 99, or sealing connection units 97, or other devices. Additional guide rollers may be used. Some rollers 120, 820 may be bowed to spread the web 13, some may move to provide web steering, some may provide web tension feedback to servo controllers, and others may be mere idlers to run the web in desired positions.

The input module 101 can be configured to allow continuous feeding of the web substrate 13 by adjoining multiple foils by welding, stapling, or other suitable means. Rolls of web substrate 13 can be provided on multiple input spools 111. A joinder device 130 can be provided to adjoin an end of each roll of the web substrate 13 to a beginning of the next roll of the web substrate 13. In one embodiment, the joinder device 130 can be a welder or a stapler. An accumulator device (not shown) may be employed to provide continuous feeding of the web substrate 13 into the apparatus 1000 while the joinder device 130 adjoins two rolls of the web substrate 13, as described in U.S. Pat. No. 7,516,164.

In one embodiment, the input module 101 may perform pre-processing steps. For example, a pre-clean process may be performed on the web substrate 13 in the input module 101. In one embodiment, the web substrate 13 may pass by a heater array (not shown) that is configured to provide at least enough heat to remove water adsorbed on the surface of the web substrate 13. In one embodiment, the web substrate 13 can pass over a roller configured as a cylindrical rotary magnetron. In this case, the front surface of web substrate 13 can be continuously cleaned by DC, AC, or RF sputtering as the web substrate 13 passes around the roller/magnetron. The sputtered material from the web substrate 13 can be captured on a disposable shield. Optionally, another roller/magnetron may be employed to clean the back surface of the web substrate 13. In one embodiment, the sputter cleaning of the front and/or back surface of the web substrate 13 can be performed with linear ion guns instead of magnetrons. Alternatively or additionally, a cleaning process can be performed prior to loading the roll of the web substrate 13 into the input module 101. In one embodiment, a corona glow discharge treatment may be performed in the input module 101 without introducing an electrical bias.

The output module 800 can include a cutting apparatus 840 configured to cut the web substrate 13 into conductive substrates 12. In the alternative, the web substrate 13 may be wound on an output spool.

In one embodiment, the input module 101 and the output module 800 can be maintained in the air ambient at all times while the process modules 200, 300, 400, 500 are maintained at vacuum during layer deposition. The web substrate 13 may be treated with deionized water in an optional water treatment module 890, within the output module 800, as described in U.S. Pat. App. Pub. No. 2017/0317227 A1, which is incorporated herein by reference in its entirety. In one embodiment, the water treatment module 890 contains a deionized water spray device 860 which is configured to spray the deionized water to the physically exposed surface of the transparent conductive oxide layer 50.

As discussed in detail below, each of the first, second, third, and fourth process modules (200, 300, 400, 500) can deposit a respective material layer to form the photovoltaic cell 10 (shown in FIG. 1A) as the web substrate 13 passes through the first, second, third, and fourth process modules (200, 300, 400, 500) sequentially.

The first process module 200 includes a first sputtering target 210, which includes the material of a first electrode, e.g., electrode 20 of the photovoltaic cell 10 illustrated in FIG. 1A. A first heater 270 can be provided to heat the web substrate 13 to an optimal temperature for deposition of the first electrode 20. In one embodiment, a plurality of first sputtering sources 210 and a plurality of first heaters 270 may be employed in the first process module 200. In one embodiment, the at least one first sputtering target 210 can be mounted on dual cylindrical rotary magnetron(s), or planar magnetron(s) sputtering sources, or RF sputtering sources. In one embodiment, the at least one first sputtering target 210 can include a molybdenum target, a molybdenum-sodium, and/or a molybdenum-sodium-oxygen target, as described in U.S. Pat. No. 8,134,069, incorporated herein by reference in its entirety.

The portion of the web substrate 13 on which the first electrode 20 is deposited is moved into the second process module 300. A p-doped chalcogen-containing compound semiconductor material is deposited to form the p-doped semiconductor layer 30, such as a sodium doped CIGS absorber layer. In one embodiment, the p-doped chalcogen-containing compound semiconductor material can be deposited employing reactive alternating current (AC) magnetron sputtering in a sputtering atmosphere that includes argon and a chalcogen-containing gas at a reduced pressure. In one embodiment, multiple metallic component targets 310 including the metallic components of the p-doped chalcogen-containing compound semiconductor material can be provided in the second process module 300.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 310 can include an alloy of all non-metallic materials in the chalcogen-containing compound semiconductor material to be deposited. For example, if the chalcogen-containing compound semiconductor material is a CIGS material, the metallic component targets 310 can include an alloy of copper, indium, and gallium. More than two targets 310 may be used.

At least one chalcogen-containing gas source 320, such as a selenium evaporator, and at least one gas distribution manifold 322 can be provided on the second process module 300 to provide a chalcogen-containing gas into the second process module 300. The chalcogen-containing gas provides chalcogen atoms that are incorporated into the deposited chalcogen-containing compound semiconductor material.

Generally speaking, the second process module 300 can be provided with multiple sets of chalcogen-containing compound semiconductor material deposition units. As many chalcogen-containing compound semiconductor material deposition units can be provided along the path of the web substrate 13 as is needed to achieve the desired thickness for the p-doped chalcogen-containing compound semiconductor material. The number of second vacuum pumps 380 may, or may not, coincide with the number of the deposition units. The number of second heaters 370 may, or may not, be commensurate with the number of the deposition units.

The chalcogen-containing gas source 320 includes a source material for the chalcogen-containing gas. The species of the chalcogen-containing gas can be selected to enable deposition of the target chalcogen-containing compound semiconductor material to be deposited. For example, if a CIGS material is to be deposited for the p-doped semiconductor layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be an effusion cell that can be heated to generate selenium vapor. Each second heater 370 can be a radiation heater that maintains the temperature of the web substrate 13 at the deposition temperature, which can be in a range from 400° C. to 800° C., such as a range from 500° C. to 700° C., which is preferable for CIGS deposition.

The chalcogen incorporation during deposition of the chalcogen-containing compound semiconductor material determines the properties and quality of the chalcogen-containing compound semiconductor material in the p-doped semiconductor layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-doped semiconductor layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 310.

In one embodiment, each metallic component target 310 can be employed with a respective magnetron (not expressly shown) to deposit a chalcogen-containing compound semiconductor material with a respective composition. In one embodiment, the composition of the metallic component targets 310 can be gradually changed along the path of the web substrate 13, so that a graded chalcogen-containing compound semiconductor material can be deposited in the second process module 300. For example, if a CIGS material is deposited as the chalcogen-containing compound semiconductor material of the p-doped semiconductor layer 30, the atomic percentage of gallium of the deposited CIGS material can increase as the web substrate 13 progresses through the second process module 300. In this case, the p-doped CIGS material in the p-doped semiconductor layer 30 of the photovoltaic cell 10 can be graded such that the band gap of the p-doped CIGS material increases with distance from the interface between the first electrode 20 and the p-doped semiconductor layer 30.

In one embodiment, the total number of metallic component targets 310 may be in a range from 3 to 20. In an illustrative example, the composition of the deposited chalcogen-containing compound semiconductor material can be graded such that the band gap of the p-doped CIGS material changes gradually or in discrete steps with distance from the interface between the first electrode 20 and the p-doped semiconductor layer 30.

While the present disclosure is described employing an embodiment in which metallic component targets 310 are employed in the second process module 300, embodiments are expressly contemplated herein in which each, or a subset, of the metallic component targets 310 is replaced with a pair of two sputtering sources (such as a copper target and an indium-gallium alloy target), or with a set of three supper targets (such as a copper target, an indium target, and a gallium target).

According to an aspect of the present disclosure, a sodium-containing material is provided within, or over, the web substrate 13. In one embodiment, sodium can be introduced into the deposited chalcogen-containing compound semiconductor material by employing a sodium-containing metal (e.g., sodium-molybdenum alloy) to deposit the first electrode 20 in the first processing module 200, by providing a web substrate 13 including sodium as an impurity, and/or by providing sodium into layer 30 during deposition by including sodium in the target 310 and/or by providing a sodium containing vapor into the module 300.

The portion of the web substrate 13 on which the first electrode 20 and the p-doped semiconductor layer 30 are deposited is subsequently passed into the third process module 400. An n-doped semiconductor material is deposited in the third process module 400 to form the n-doped semiconductor layer 40 illustrated in the photovoltaic cell 10 of FIG. 1A. The third process module 400 can include, for example, a third sputtering target 410 (e.g., a CdS target) and a magnetron (not expressly shown). The third sputtering target 410 can include, for example, a rotating AC magnetron, an RF magnetron, or a planar magnetron. A heater 470 may be located in the module 400.

Subsequently, an n-type semiconductor layer 40, such as an n-type CdS window layer is deposited over the p-type absorber layer 30 to form a p-n junction. Sodium atoms diffuse from the web substrate 13 and/or from the first electrode 20 into the deposited semiconductor materials to form a material stack 30, 40 including sodium at the atomic concentration greater than 1×10¹⁹/cm³. Specifically, sodium provided in the first electrode 20 or in the web substrate 13 can diffuse into the deposited chalcogen-containing compound semiconductor material during deposition of the chalcogen-containing compound semiconductor material. The sodium concentration in the deposited chalcogen-containing compound semiconductor material can be in a range from 1.0×10¹⁹/cm³ to 5×10²⁰/cm³. The sodium atoms tend to pile up at a high concentration near the growth surface of the chalcogen-containing compound semiconductor material, thereby causing the sodium atoms to travel forward as the deposition process progresses.

Thus, a material stack 30, 40 including a p-n junction is formed on the web substrate 13. In one embodiment, the material stack 30, 40 can comprise a stack of a p-doped metal chalcogenide semiconductor layer (as the p-doped semiconductor layer 30) and an n-doped metal chalcogenide semiconductor layer (as the n-doped semiconductor layer 40). In one embodiment, the p-doped metal chalcogenide semiconductor layer can comprise copper indium gallium selenide (CIGS), and the n-doped metal chalcogenide semiconductor layer can comprise a material selected from a metal selenide, a metal sulfide (e.g., CdS), and an alloy thereof. The material stack 30, 40 can include sodium at an atomic concentration greater than 1×10¹⁹/cm³ (such as about 1×10²⁰/cm³).

The portion of the web substrate 13 on which the first electrode 20, the p-doped semiconductor layer 30, and the n-doped semiconductor layer 40 are deposited is subsequently passed into the fourth process module 500. A transparent conductive oxide material is deposited in the fourth process module 500 to form the second electrode comprising a transparent conductive layer 50 illustrated in the photovoltaic cell 10 of FIG. 1A. The fourth process module 400 can include, for example, a fourth sputtering target 510, a heater 570, and a magnetron (not expressly shown). The fourth sputtering target 510 can include, for example, a ZnO, AZO or ITO target and a rotating AC magnetron, an RF magnetron, or a planar magnetron. A transparent conductive oxide layer 50 is deposited over the material stack 30, 40 including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 13 passes into the output module 800. In one embodiment, the deionized water can be applied to the physically exposed surface of the transparent conductive oxide layer 50 by spraying as illustrated in FIG. 4. The spraying operation can be performed employing at least one spray device 860 configured to spray the fluid, such as deionized water, on the physically exposed surface of the transparent conductive oxide layer 50 located over the front surface of the processed web substrate 13. The spray device 860 may comprise one or more nozzles or shower heads, such as one or more rows of nozzles, which spray water onto layer 50 located over the web substrate 13. Gravity may be employed to retain the sprayed deionized water on the surface of the transparent conductive oxide layer 50. For example, the web substrate 13 may be at an incline such that the deionized water stays on the surface of the transparent conductive oxide layer 50.

The positions of the various output-side rollers 820 can be adjusted to retain the sprayed deionized water on the surface of the transparent conductive oxide layer 50. A deionized water tank 850 can be employed as a reservoir of the deionized water to be supplied to the at least one spray device 860. Alternatively, a water pipe connected to an ion exchange resin or electro-deionization apparatus may be used instead of the deionized water tank 850 to supply deionized water to the spray device 860 (e.g., nozzle(s) or shower head(s)).

At least one dryer 870 can be employed to remove residual deionized water from the surface of the transparent conductive oxide layer 50. The dryer 870 may comprise a fan or blower configured to blow filtered air (or inert gas such as nitrogen) toward the surface of the transparent conductive oxide layer 50. In one embodiment, the direction of the filtered air from the at least one dryer 870 can be directed to push the residual deionized water off the front surface of the transparent conductive oxide layer 50 in conjunction with the gravitational force, for example, by directing the air flow downward and/or outward (away from the center of the web substrate 13). Alternatively, the dryer 870 may comprise a heater which evaporates the water in addition to or instead of the fan or blower. The web substrate 13 can then be cut by the cutting apparatus 840.

In one embodiment, deionized water can be applied to the physically exposed surface of the transparent conductive oxide layer for long enough time to allow bulk diffusion of sodium atoms from within the bulk (i.e., interior) of the transparent conductive oxide layer 50 to reach the outer surface of layer 50 to be rinsed off the outer surface. Sodium is a fast diffuser within the transparent conductive oxide layer 50, the p-doped semiconductor layer 30 and the n-doped semiconductor layer 40. In one embodiment, the deionized water can be applied to the physically exposed surface of the transparent conductive oxide layer for a duration in a range from 5 seconds to 10 minutes. In one embodiment, the deionized water can be applied to the physically exposed surface of the transparent conductive oxide layer for a duration in a range from 20 seconds to 3 minutes.

In one embodiment, the deionized water is applied at an elevated temperature greater than 50 degrees Celsius. In one embodiment, the deionized water is applied at an elevated temperature in a range from 50 degrees Celsius to 100 degrees Celsius. In one embodiment, the deionized water is applied at an elevated temperature in a range from 60 degrees Celsius to 95 degrees Celsius. In one embodiment, the deionized water is applied at an elevated temperature in a range from 70 degrees Celsius to 80 degrees Celsius. In one embodiment, a fluid heater 874 (e.g., a resistive heater) and/or a substrate heater 872 may be employed to maintain the temperature of the fluid (e.g., water provided from the spray device 860) and/or of the web substrate 13 at an elevated temperature in a range from 50 degrees Celsius to 100 degrees Celsius. The fluid heater may be located adjacent to the tank 850 and/or adjacent to the spray device 860 to heat the fluid being provided from the tank 850 through the spray device 860 over the moving web substrate 13. In another embodiment, the water treatment module 890 may be omitted.

An interconnection module 900 is located downstream of the fluid treatment module 890 in the web substrate 13 moving direction. The interconnection module 900 is configured to apply an electrically conductive interconnect 25 to electrically connect adjacent photovoltaic cells 10 after the web substrate 13 is cut to separate individual solar cells 10 by the cutting device 840. For example, first and second solar cells 10A, 10B and the interconnect 25 may be placed on a support, such as a table or conveyor 902, using a handling tool 904, such as a pick and place arm or another tool such that the interconnect 25 overlaps the cells 10. For example, the second cell 10B may be placed on the support 902 first, followed by placing the interconnect 25 over the second electrode 50 of the second cell 10B, such that a portion of the interconnect 25 hangs off to the side of the second cell 10B, following by placing the substrate 12 side of the first cell 10A on the portion of the interconnect 25 that hangs off to the side of the second cell 10B, to electrically connect the first and second cells 10, 10B in series. The dielectric layers 14, 16 may have a respective top and bottom adhesive surface that face the hybrid layer 18 and the respective cells 10A, 10B, to physically attach the interconnect 25 to the cells 10A, 10B. The handling tool 904 may press the dielectric layers 14, 16 and the cells 10A, 10B together to attach the adhesive surfaces to the cells 10A, 10B. Other suitable interconnection modules 900 may also be used.

While sputtering was described as the preferred method for depositing all solar cell layers onto the web substrate 13, some layers may be deposited by MBE, CVD, evaporation, plating, etc.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the embodiments of the present disclosure.

What is claimed is:

1. A photovoltaic device interconnect having a first connection region, a second connection region, and an overlap region disposed between the first and second connection regions, the interconnect comprising:
a first dielectric layer disposed in the first connection region and the overlap region;
a second dielectric layer disposed in the second connection region and overlapped with the first dielectric layer in the overlap region;
an electrically conductive element comprising a wire or metal foil, disposed on an upper surface of the first dielectric layer; and
an electrically conductive network of nanowires disposed on a lower surface of the second dielectric layer and electrically connected to the conductive element in the overlap region.

2. The interconnect of claim 1, wherein the first and second dielectric layers comprise a flexible, transparent, dielectric material.

3. The interconnect of claim 2, wherein the first and second dielectric layers each comprise a transparent polymeric film, a transparent non-polymeric film, a transparent oligomer film, or a combination thereof.

4. The interconnect of claim 1, wherein the nanowires comprise electrically conductive metal oxide nanowires, metal nanowires, or carbon nanotubes.

5. The interconnect of claim 1, wherein the nanowires comprise silver, nickel, or copper, or a combination thereof.

6. The interconnect of claim 1, wherein:
the nanowires have an average aspect ratio ranging from about 10 to about 1000; and
the nanowires have an average diameter ranging from about 10 nm to about 500 nm.

7. The interconnect of claim 1, wherein:
an upper surface of the conductive element is exposed outside of the second dielectric layer, in the first connection region; and
a lower surface of the network is exposed outside of the second dielectric layer, in the second connection region.

8. The interconnect of claim 1, wherein the network has a higher concentration of nanowires in the overlap region than in the second connection region.

9. The interconnect of claim 1, wherein the network has an optical transparency of at least 85%.

10. The interconnect of claim 1, wherein:
the conductive element comprises the wire; and
the diameter of the wire ranges from about 60 microns to about 1.5 mm; and
the wire extends through the first contact region and the overlap region in a serpentine pattern.

11. The interconnect of claim 1, wherein the surface area of the first dielectric layer is smaller than the surface area of the second dielectric layer.

12. A photovoltaic device comprising:
the interconnect of claim 1;
an electrically conductive substrate; and
a first solar cell disposed on an upper surface of the substrate, the first solar cell comprising an absorber layer disposed between an anode and a cathode,
wherein, in the second connection region, the network is electrically connected to an upper surface of the first solar cell.

13. The device of claim 12, wherein the first dielectric layer is attached to the first solar cell and to the second dielectric layer using an adhesive.

14. The device of claim 12, wherein:
the absorber layer comprises p-type doped copper indium gallium selenide material;
the cathode comprises a transparent conductive material;
the anode comprises a metal; and
the solar cell further comprises a buffer layer comprising n-doped semiconductor material, disposed between the absorber layer and the cathode.

15. The device of claim 12, further comprising a second solar cell disposed on an upper surface of an electrically conductive substrate, the second solar cell comprising an absorber layer disposed between an anode and a cathode,
wherein the conductive element is electrically connected to a lower surface of the substrate of the second solar cell in the first connection region.

16. The device of claim 15, wherein the conductive element is electrically connected to the anode of the second solar cell via the substrate of the second solar cell.

17. The device of claim 15, wherein a portion of the first dielectric layer is disposed on the upper surface of the first solar cell.

18. A method of making a photovoltaic device interconnect, comprising:
disposing an electrically conductive element comprising a conductive wire or metal foil on a transparent first dielectric layer;
applying the nanowire solution to a transparent second dielectric layer to form an electrically conductive network of nanowires on the second dielectric layer;
partially overlapping the first and second dielectric layers; and
adhering overlapped portions of the first and second dielectric layers to one another, such that a portion of the conductive element electrically contacts a portion of the network.

19. The method of claim 18, wherein:
the nanowire solution is applied to an upper surface of the first second dielectric layer; and
the method further comprises inverting the second dielectric layer before partially overlapping the first and second dielectric layers.

20. The method of claim 18, wherein a higher concentration of the nanowires is applied to a portion of the second dielectric layer that overlaps with the first dielectric layer than to a remaining portion of the second dielectric layer.
